(19) United States
(12) Patent Application Publication
(10) Pub. No.: US 2024/0419878 A1
(43) Pub. Date: Dec. 19, 2024

(54) SYNTHESIS OF SIMULATION-DIRECTED STATEMENTS

(71) Applicant: Xilinx, Inc., San Jose, CA (US)

(72) Inventors: Anil Kumar A V, Salarpuria Sattva Knowledge City (IN); Alok Mistry, Salarpuria Sattva Knowledge City (IN)

(73) Assignee: Xilinx, Inc., San Jose, CA (US)

(21) Appl. No.: 18/211,465

(22) Filed: Jun. 19, 2023

(51) Int. Cl. G06F 30/327; G06F 30/31; G06F 30/323

(52) U.S. Cl. CPC G06F 30/327; G06F 30/31; G06F 30/323

(57) ABSTRACT

A method, system, and circuit arrangement involve synthesizing a circuit design specified in a register transfer level (RTL) specification into a netlist. The RTL specification includes an assert statement that specifies a conditional expression involving one or more signals specified in the circuit design to be checked during simulation, and the synthesizing includes synthesizing the assert statement into netlist elements. The design tool places and routes the netlist into a circuit design layout and generates implementation data from the layout.

### TECHNICAL FIELD

The disclosure generally relates to synthesis of simulation-directed statements in a register transfer level circuit design.

### BACKGROUND

Engineers simulate the behavior of circuits on computer systems in order to evaluate the functional behavior of a circuit design. If the simulation shows that the circuit will behave incorrectly, the circuit design can be modified to include debugging statements that can assist in identification of the source of an error. An example of a debugging statement is the “assert” statement. An assert statement can be included in register transfer level (RTL) code for the purpose of instructing the simulator to check the value of a “property” or “condition” specified in the statement. The simulator can alert the engineer when the condition is satisfied, which can be useful in debugging a design.

### SUMMARY

A disclosed method includes synthesizing a circuit design specified in a register transfer level (RTL) specification into a netlist by a design tool. The RTL specification includes an assert statement that specifies a conditional expression involving one or more signals specified in the circuit design to be checked during simulation, and the synthesizing includes synthesizing the assert statement into netlist elements. The method includes placing and routing the netlist into a circuit design layout by the design tool and generating implementation data from the layout by the design tool.

A disclosed circuit arrangement includes a plurality of sticky registers. Each sticky register corresponds to an assert statement specified in a circuit design. The circuit arrangement includes detection circuitry configured to detect logic states of conditional expressions specified in the assert statements. Each conditional expression involves one or more signals of the circuit design. The detection circuitry is configured to store values that indicate the logic states of the conditional expression in the plurality of sticky registers. The circuit arrangement includes a status register and assertion-enable circuitry coupled to the plurality of sticky registers. The assertion-enable circuitry is configured to sample the sticky registers and to store the values from the sticky registers at bit locations in the status register. Each bit location is associated with an assert statement. The circuit arrangement includes readback circuitry coupled to the status register and configured to read and output contents of the status register.

A disclosed system includes one or more computer processors configured to execute program code and a memory arrangement coupled to the one or more computer processors. The memory arrangement is configured with instructions of a design tool that when executed by the one or more computer processors cause the one or more computer processors to perform operations including synthesizing a circuit design specified in a register transfer level (RTL) specification into a netlist. The RTL specification includes an assert statement that specifies a conditional expression involving one or more signals specified in the circuit design to be checked during simulation. The synthesizing includes synthesizing the assert statement into netlist elements that define a status register and logic to capture in the status register a logic state of the conditional expression. The operations include placing and routing the netlist into a circuit design layout generating implementation data from the layout.

Other features will be recognized from consideration of the Detailed Description and Claims, which follow.

### BRIEF DESCRIPTION OF THE DRAWINGS

Various aspects and features of the method and system will become apparent upon review of the following detailed description and upon reference to the drawings in which:

FIG. 1 shows a flowchart of an exemplary process of synthesizing assert statements in a circuit design and realizing the circuit design on prototyping and emulation platforms;

FIG. 2 shows an exemplary integrated circuit (IC) device configured to implement assertions specified in a circuit design;

FIG. 3 is a flowchart of an exemplary process of the assertion core circuitry;

FIG. 4 shows an exemplary assertion browser window of a debug tool that provides a user interface for the display of assertion hits and controls for enabling/disabling logging of assertion hits and clearing assertion hits;

FIG. 5 is a block diagram illustrating an exemplary data processing system; and

FIG. 6 shows a programmable integrated circuit (IC) on which circuitry generated by the disclosed processes can be implemented.

### DETAILED DESCRIPTION

In the following description, numerous specific details are set forth to describe specific examples presented herein. It should be apparent, however, to one skilled in the art, that one or more other examples and/or variations of these examples, all of which are non-limiting, may be practiced without all the specific details given below. In other instances, well known features have not been described in detail so as not to obscure the description of the examples herein. For ease of illustration, the same reference numerals may be used in different diagrams to refer to the same elements or additional instances of the same element.

For large, complex circuit designs, such as those targeted to a system-on-chip (SoC), a simulation may run for an extended period of time and require considerable computer system resources. To reduce test and verification time, a prototyping or an emulation platform may be used instead of a simulation system. Prototyping and emulation platforms typically includes a field programmable gate array (FPGA) that can be configured with an implementation of the circuit design. Though a prototyping/emulation platform can greatly reduce the time required for test and verification, the platform/emulation platform may offer less debugging support than a simulation system.

Assert statements are often included in a circuit design for debugging a design using a simulator. In compiling the circuit design for simulation, the simulation compiler generates constructs for effecting the assert statements. However, conventional approaches to implementing a circuit design for prototyping/emulation do not support assert statements, because synthesis processes ignore assert statements as non-synthesizable constructs in an RTL specification.

Without circuitry to implement assertions, error conditions may go undetected during prototyping/emulation and necessitate numerous debug runs involving added logic probes on suspect signals. For example, an integrated logic analyzer can be used to localize errors by probing signals relevant to debugging and identifying trigger points. Using an integrated logic analyzer is a manual and time consuming effort and can be tedious. In addition, an integrated logic analyzer does not provide the flexibility of collecting and displaying a text based log of all conditions that have been hit.

The disclosed methods and system enable synthesis of assert statements and realization on an prototyping/emulation platforms. The methods and system do not require modifications to the RTL specification or user intervention to implement the assertion, thereby making the circuit design portable across simulation and prototyping/emulation platforms. The methods and system provide the benefits of simulation with significant reductions in the durations of debug runs and without incurring the substantial requirements for computer resources that simulation requires.

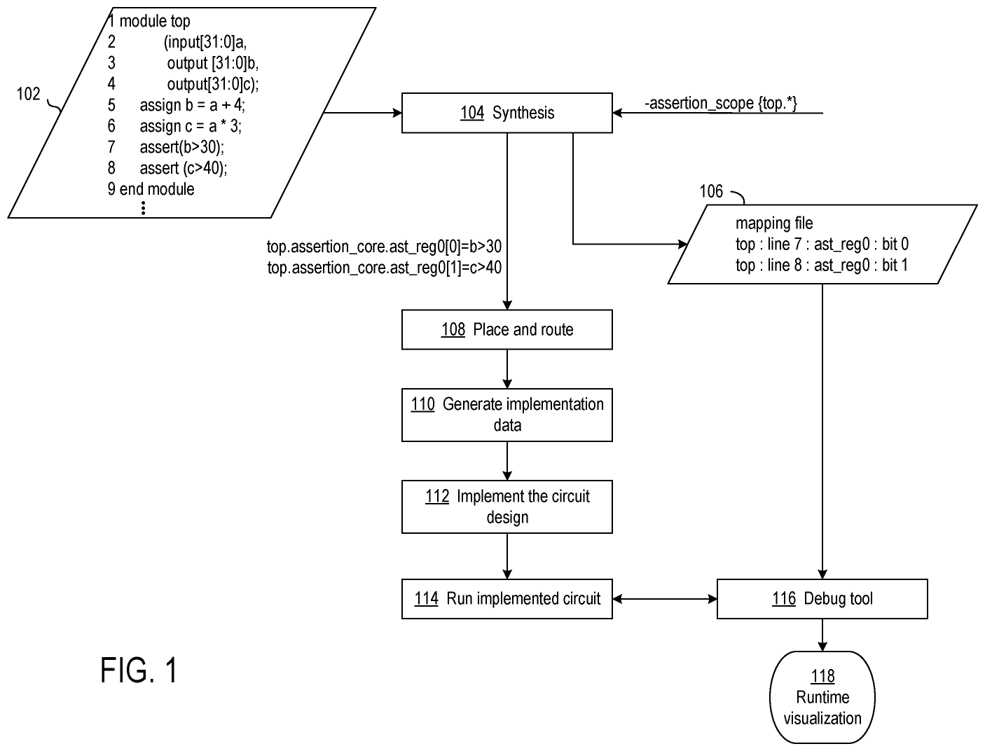

FIG. 1 shows a flowchart of an exemplary process of synthesizing assert statements in a circuit design and realizing the circuit design on various platforms. The synthesis process 104 of a design tool inputs an RTL specification of a circuit design 102. As a non-limiting example, the circuit design includes a module named “top,” and the module has assert statements in lines 7 and 8. The conditional expressions specified by the assert statements are b>30 and c>40, respectively.

In invoking the synthesis process, a user can specify the scope of the circuit design for which assertions are to be synthesized. For example, the user can limit the synthesis of assertions to certain modules of the circuit design, causing assertions in some modules to be synthesized and bypassing the synthesis of assertions in other modules. In the example, the switch input,

“-assertion_scope{top.*},” specifies that assertions in the module, top, and assertions in modules within the hierarchy of top are to be synthesized. According to one implementation, the synthesis process bypasses synthesis of all assertions in response to the absence of the switch input.

Assertions are synthesized by the synthesis process by generating netlist elements that define one or more status register and logic to capture the state(s) of a signal(s) that indicates a logic state of the conditional expression of the assertion. For brevity, when the conditional expression of an assertion evaluates to the desired logic state (e.g., logic TRUE), the assertion is said to be “hit.” “Signal” as used herein refers to either a single signal or a group of signals, depending on the context. A single logic value indicated by the state of a bi-stable circuit is a signal as is a multi-bit value, such as an integer or floating point value in register.

Based on the exemplary RTL specification, the synthesis process generates netlist elements to evaluate whether or not the value of b is greater than the constant 30 and netlist elements to evaluate whether or not the value of c is greater than the constant 40. A textual representation of the netlist elements generated from the assertions in circuit design 102 are shown in FIG. 1 as:

top.assertion_core.ast_reg0[0]=b>30
top.assertion_core.ast_reg0[1]=c>40

The “ast_reg” is a status register in the assertion_core module. In response to b>30 evaluating to TRUE during circuit operation, bit 0 of the status register 0 is set to logic 1, and in response to c>40 evaluating to TRUE, bit 1 of the status register 0 is set to logic 1.

The number of status registers specified by the synthesis process depends on the number of assertions to be synthesized and the chosen register size. For example, each status register can be a 32-bit register which can accommodate 32 assertions. The assertions of the circuit design are mapped to respective bit locations in the status register(s) by the synthesis process, and the synthesis process generates a mapping file 106 that can be used by a debug tool 116 in generating useful information to a user. The mapping file can indicate for each synthesized assertion, the module and line number of the assertion, and the status register and bit position at which the status of the assertion is indicated.

The netlist elements associated with signaling an assertion hit include an individual “sticky” register (e.g., a flip-flop) that stores a logic value indicative of the hit. Once the assertion is hit, the hit value in the sticky register remains until it is cleared by user control, even though the assertion may revert back to a no-hit state during circuit operation.

Different modules of a circuit design may be clocked by clock signals of different clock domains, and the logic that implements the assertions in those modules are clocked by the respective clock signals. To ensure that the hits of all assertions are captured, the status register(s) is clocked at the maximum frequency of the circuit design, which can be different from the frequency(ies) of the clock domains in which the assertions are captured.

A feature of the disclosed approaches to synthesizing assertions provides a user with the ability to enable and disable capturing of individual assertions at debug runtime. “Debug runtime” refers to the time period during which an integrated circuit (IC) device operates as configured according to the circuit design. The synthesis process generates netlist elements to implement control registers to indicate which assertions are to have hits captured in the status register(s), along with control logic for updating the control registers. The assertions of the circuit design are mapped to respective bit locations in the control register(s) by the synthesis process. An assertion hit can be indicated in the status register in response to the associated control bit having a bit value indicated enabled AND the logic state of the sticky register indicating a hit.

Another feature of the disclosed approaches to synthesizing assertions provides a user with the ability to clear assertion hits indicated in the status register(s) at debug runtime. The synthesis process generates netlist elements that write values to the status register(s) and reset the sticky registers to states that indicate no assertions have been hit.

The synthesis process also generates readback logic for reading hit information from the status registers. In support of the readback logic, the control logic for updating the control registers, and the logic for clearing the status and sticky registers, the synthesis process generates a boundary scan interface to the assertion logic. During debug runtime, the assertion logic support circuitry receives controls from the debug tool via the boundary scan interface, as specified by the standard, IEEE 1149, for example.

Following synthesis, at blocks 108, 110, and 112, the design tool places and routes the generated netlist, generates implementation data, and implements the circuit design on an integrated circuit device according to recognized processes.

At block 114, the implemented circuit is operated with external control by the debug tool 116. The debug tool, which can be a component of the design tool that provides the implementation flow, provides a user interface for enabling and disabling capturing of assertions, clearing captured assertions, reading back captured assertions and providing runtime visualization 118 of assertions. The runtime visualization can include display of data that identify the assert statement in response to the status register indicating the logic state of the conditional expression, and/or the assert statement from the RTL specification in response to user selection of the data that identify the assert statement.

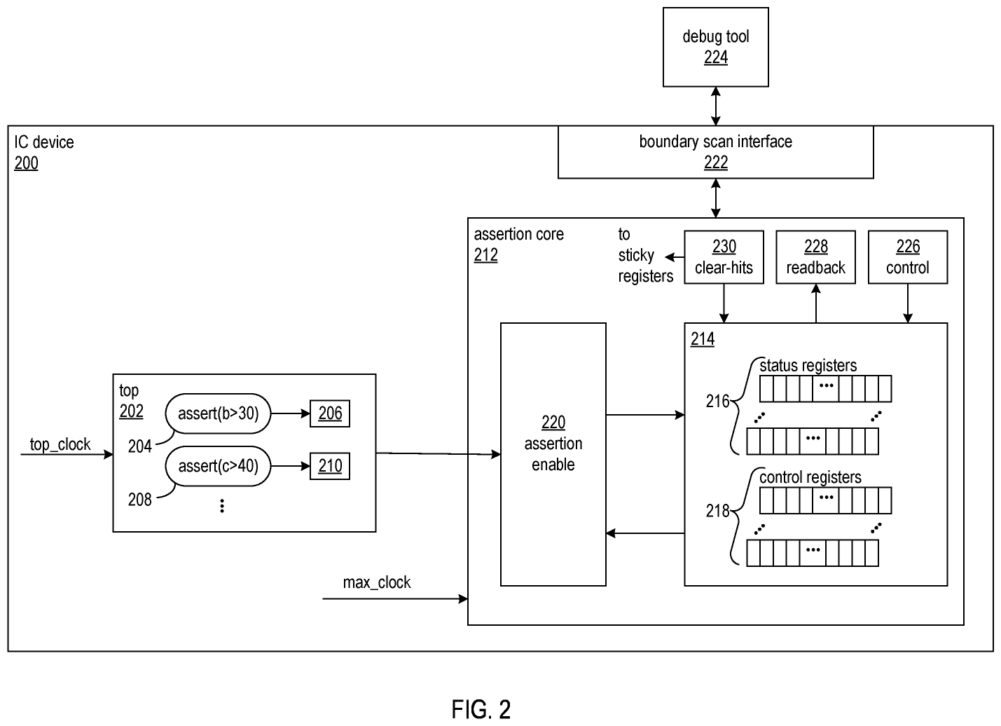

FIG. 2 shows an exemplary integrated circuit (IC) device 200 configured to implement assertions specified in a circuit design. The IC device can be a system-on-chip (SoC), system-in-package (SiP), FPGA, or application specific integrated circuit (ASIC).

Block 202 represents the circuitry generated from module “top” in the exemplary RTL specification of FIG. 1. Logic circuitry 204 updates sticky register 206 in response to detecting that signal b is greater than 30, and logic circuitry 208 updates sticky register 210 in response to detecting that signal c is greater than 40. The sticky registers can be set-reset flip-flops that are enabled by the clock signal, top_clock, to the top module. Though not shown, it will be recognized that other modules of the circuit design can be clocked by clock signals other than top_clock.

The assertion core 212 circuitry is generated by the synthesis process to support the logging and reporting of assertion hits. The assertion core includes storage circuitry 214 and logic circuitry that supports various functions pertaining to assertions. The storage circuitry can be individual registers or random access memory (RAM), depending on design requirements. For purposes of illustration, the storage circuitry used to log the status of assertions and to control the logging is shown to include status registers 216 and control registers 218. According to an implementation, each bit (“status bit”) in a status register and a corresponding bit (“control bit”) in a control register are together associated with one of the sticky registers and thereby one of the assertions.

The assertion enable circuitry 220 logs assertion hits in the status registers based on states of the sticky registers and the corresponding control registers. The assertion enable circuitry is coupled to receive signals from the sticky registers, such as sticky registers 206 and 210 and any additional sticky registers implemented for assertions. Also, the assertion enable circuitry is coupled to receive the control bit signals from the control registers and is coupled to write status bits to the status registers. In response to the logic state of a sticky register indicating an assertion hit and the state of the associated control bit indicating that assertion capture is enabled, the assertion enable circuitry updates the associated status bit. In order to ensure that no assertion hit is missed, the assertion core circuitry samples sticky registers at the maximum clock rate of the circuit design, which is shown as the clock signal, max_clock.

The boundary scan interface 222 provides a channel for control by the debug tool 224 over the functions of the assertion core circuitry. The debug tool provides a user interface for showing data indicating assertions that have been hit and data that indicate which assertions are enabled. The debug tool also provides a user interface for controlling the enabling/disabling of assertions and for clearing assertion hits. The debug tool interfaces with control logic 226, readback logic 228, and clear-hits 230 logic of the assertion core circuitry via the boundary scan interface.

The control logic 226 is coupled to the control registers. In response to user controls input to the debug tool and communicated to the control logic via the boundary scan interface, the control logic accesses bits in the control registers to enable/disable logging of individual assertion hits.

The readback logic 228 is coupled to the status registers. The debug tool polls the status registers by periodically activating the readback logic via the boundary scan interface to read the contents of the status registers. Based on the values of the bits in the status registers and the mapping file 106 (FIG. 1) generated by the synthesizer, the debug tool displays data that indicate which assertions have been hit.

The clear-hits 230 logic is coupled to the status registers and to the sticky registers. In response to user control input to the debug tool and communicated to the clear-hit logic via the boundary scan interface, the clear-hit logic configures status registers and sticky registers with values to indicate no assertions have been hit.

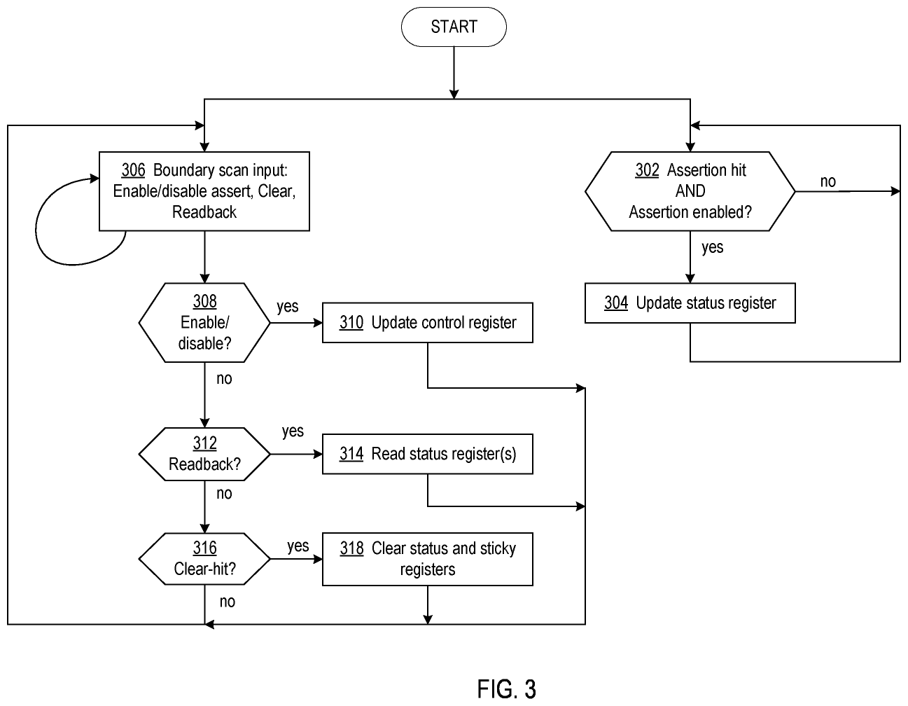

FIG. 3 is a flowchart of an exemplary process of the assertion core circuitry. The process can have two parallel sets of operations. The right leg of the flowchart shows operations associated with processing assertion hits, and the left leg of the flowchart shows operations associated with processing controls from the debug tool.

In response to an assertion hit as indicated by the state of a sticky register and the state of the corresponding control indicating that the assertion is enabled, decision block 302 directs the process to block 304. If no assertion hit is detected or an assertion hit was detected and the assertion was not enabled as indicated by the associated control bit, the process continues to monitor for assertion hits in decision block 302. At block 304, the debug process updates the bit associated with the assertion in the status register with a value that indicates the assertion was hit and returns to monitor assertion hits at decision block 302.

At block 306, the process waits for boundary scan input from the debug tool. In response to an enable/disable control from the debug tool, decision block 308 directs the process to block 310 to update the control register. The enable/disable control from the debug tool specifies which bit of the control register (and which control register for multiple control registers) to configure with a value to enable/disable logging of an assertion hit. The process returns to block 306 to wait for boundary scan input from the debug tool.

In response to a readback control from the debug tool, decision block 312 directs the process to block 314. At block 314, the assertion core circuitry reads the contents of the status register(s) and communicates the data back to the debug tool via the boundary scan interface. The process returns to block 306 to wait for boundary scan input from the debug tool.

In response to a clear-hit control from the debug tool, decision block 316 directs the process to block 318. At block 318, the assertion core circuitry configures the status register and sticky registers with values that indicate no assertions have been hit. The process returns to block 306 wait for boundary scan input from the debug tool.

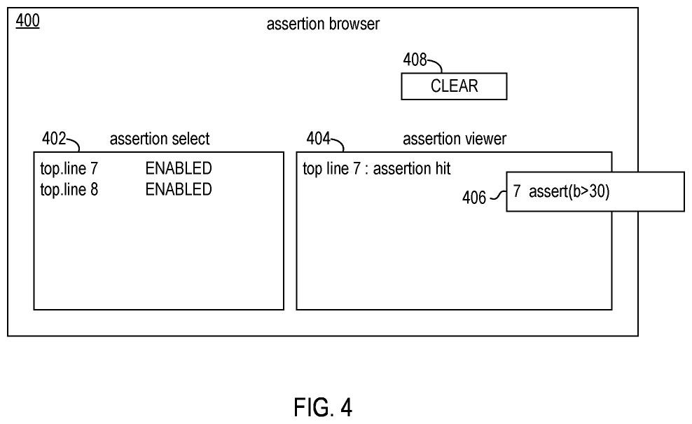

FIG. 4 shows an exemplary assertion browser window 400 of a debug tool that provides a user interface for the display of assertion hits and controls for enabling/disabling logging of assertion hits and clearing assertion hits. The data shown in the assertion browser corresponds to the exemplary RTL module in FIG. 1.

The assertion select window 402 displays data that indicate the enable/disable status of the synthesized assertions. According to the example, assertions are enabled for the assertion statements of lines 7 and 8 of the module, top, in the RTL specification 102 (FIG. 1). According to the disclosed method and system, a user can toggle the enable/disable status of an assertion by selecting, such as by a click of a mouse, the line of text describing the status of the assertion.

The assertion viewer window 404 displays data that indicate which assertions have been hit. According to the example, the assertion associated with line 7 of the RTL module was hit, and the assertion associated with line 8 of the RTL module has not been hit. According to another feature of the method and system, the debug tool can display the RTL statement associated with a hit assertion in response to the user selecting the data that indicate the hit assertion. For example, the debug tool can display the RTL statement of line 7 in window 406 in response to user selection of the corresponding text in the assert viewer window. Additional lines of RTL code surrounding the assert statement of line 7 can also be displayed in window 406.

The CLEAR button 408 in the assertion browser window provides the user with control for clearing the status registers and sticky registers. In response to user selection of the CLEAR button, the debug tool communicates controls to the assertion core circuitry via the boundary scan interface for clearing the registers.

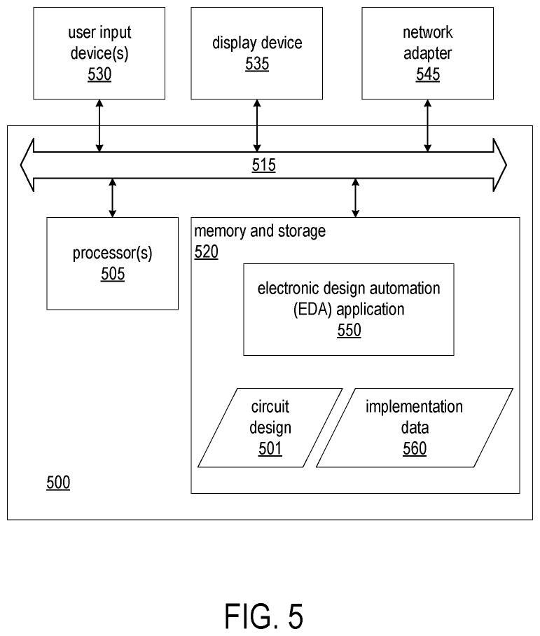

FIG. 5 is a block diagram illustrating an exemplary data processing system (system) 500. System 500 is an example of an electronic design automation (EDA) system. As pictured, system 500 includes at least one processor circuit (or “processor”), e.g., a central processing unit (CPU) 505 coupled to memory and storage arrangement 520 through a system bus 515 or other suitable circuitry. System 500 stores program code and circuit design 501 within memory and storage arrangement 520. Processor 505 executes the program code accessed from the memory and storage arrangement 520 via system bus 515. In one aspect, system 500 is implemented as a computer or other data processing system that is suitable for storing and/or executing program code. It should be appreciated, however, that system 500 can be implemented in the form of any system including a processor and memory that is capable of performing the functions described within this disclosure.

Memory and storage arrangement 520 includes one or more physical memory devices such as, for example, a local memory (not shown) and a persistent storage device (not shown). Local memory refers to random access memory or other non-persistent memory device(s) generally used during actual execution of the program code. Persistent storage can be implemented as a hard disk drive (HDD), a solid state drive (SSD), or other persistent data storage device. System 500 may also include one or more cache memories (not shown) that provide temporary storage of at least some program code and data in order to reduce the number of times program code and data must be retrieved from local memory and persistent storage during execution.

Input/output (I/O) devices such as user input device(s) 530 and a display device 535 may be optionally coupled to system 500. The I/O devices may be coupled to system 500 either directly or through intervening I/O controllers. A network adapter 545 also can be coupled to system 500 in order to couple system 500 to other systems, computer systems, remote printers, and/or remote storage devices through intervening private or public networks. Modems, cable modems, Ethernet cards, and wireless transceivers are examples of different types of network adapter 545 that can be used with system 500.

Memory and storage arrangement 520 may store an EDA application 550. EDA application 550, being implemented in the form of executable program code, is executed by processor(s) 505. As such, EDA application 550 is considered part of system 500. System 500, which is configured as a design tool while executing EDA application 550, receives and operates on circuit design 501. In one aspect, system 500 performs a design flow on circuit design 501, and the design flow may include synthesis (including synthesis of assert statement), mapping, placement, routing, and generating implementation data 560.

EDA application 550, circuit design 501, implementation data 560, and any data items used, generated, and/or operated upon by EDA application 550 are functional data structures that impart functionality when employed as part of system 500 or when such elements, including derivations and/or modifications thereof, are loaded into an IC such as a programmable IC causing implementation and/or configuration of a circuit design within the programmable IC.

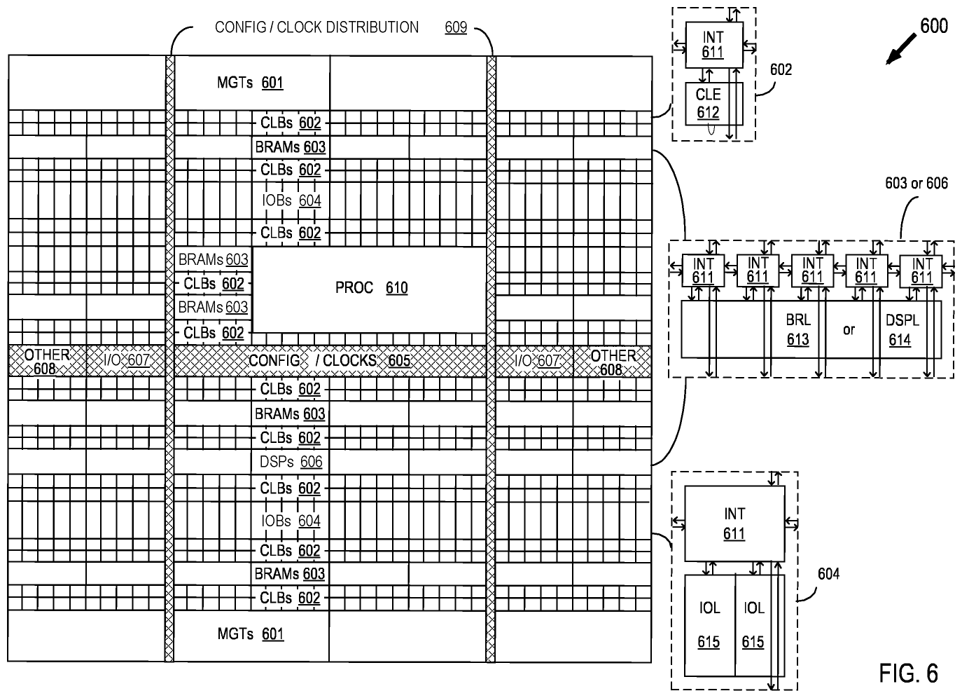

FIG. 6 shows a programmable integrated circuit (IC) 600 on which circuitry generated by the disclosed processes can be implemented. The programmable IC may also be referred to as a System On Chip (SOC) that includes field programmable gate array logic (FPGA) along with other programmable resources. FPGA logic may include several different types of programmable logic blocks in the array. For example, FIG. 6 illustrates programmable IC 600 that includes a large number of different programmable tiles including multi-gigabit transceivers (MGTs) 601, configurable logic blocks (CLBs) 602, random access memory blocks (BRAMs) 603, input/output blocks (IOBs) 604, configuration and clocking logic (CONFIG/CLOCKS) 605, digital signal processing blocks (DSPs) 606, specialized input/output blocks (I/O) 607, for example, clock ports, and other programmable logic 608 such as digital clock managers, analog-to-digital converters, system monitoring logic, and so forth. Some programmable IC having FPGA logic also include dedicated processor blocks (PROC) 610 and internal and external reconfiguration ports (not shown). Circuit designs processed according to the disclosed methods and systems can also be implemented as ASICs or on an adaptive compute acceleration platform (ACAP). An ACAP has FPGA fabric with distributed memory and hardware-programmable DSP blocks, a multicore SoC, and one or more software programmable, yet hardware adaptable, compute engines, all connected through a network on chip (NoC).

In some FPGA logic, each programmable tile includes a programmable interconnect element (INT) 611 having standardized connections to and from a corresponding interconnect element in each adjacent tile. Therefore, the programmable interconnect elements taken together implement the programmable interconnect structure for the illustrated FPGA logic. The programmable interconnect element INT 611 also includes the connections to and from the programmable logic element within the same tile, as shown by the examples included at the top of FIG. 6.

For example, a CLB 602 can include a configurable logic element (CLE) 612 that can be programmed to implement user logic, plus a single programmable interconnect element INT 611. A BRAM 603 can include a BRAM logic element (BRL) 613 in addition to one or more programmable interconnect elements. Typically, the number of interconnect elements included in a tile depends on the height of the tile. The illustrated BRAM tile has the same height as five CLBs, but other numbers (e.g., four) can also be used. A DSP tile 606 can include a DSP logic element (DSPL) 614 in addition to an appropriate number of programmable interconnect elements. An IOB 604 can include, for example, two instances of an input/output logic element (IOL) 615 in addition to one instance of the programmable interconnect element INT 611. As will be clear to those of skill in the art, the actual I/O bond pads connected, for example, to the I/O logic element 615, are manufactured using metal layered above the various illustrated logic blocks, and typically are not confined to the area of the input/output logic element 615.

A columnar area near the center of the die (shown shaded in FIG. 6) is used for configuration, clock, and other control logic. Horizontal areas 609 extending from this column are used to distribute the clocks and configuration signals across the breadth of the programmable IC. Note that the references to “columnar” and “horizontal” areas are relative to viewing the drawing in a portrait orientation.

Some programmable ICs utilizing the architecture illustrated in FIG. 6 include additional logic blocks that disrupt the regular columnar structure making up a large part of the programmable IC. The additional logic blocks can be programmable blocks and/or dedicated logic. For example, the processor block PROC 610 shown in FIG. 6 spans several columns of CLBs and BRAMs.

Note that FIG. 6 is intended to illustrate only an exemplary programmable IC architecture. The numbers of logic blocks in a column, the relative widths of the columns, the number and order of columns, the types of logic blocks included in the columns, the relative sizes of the logic blocks, and the interconnect/logic implementations included at the top of FIG. 6 are purely exemplary. For example, in an actual programmable IC, more than one adjacent column of CLBs is typically included wherever the CLBs appear, to facilitate the efficient implementation of user logic.

Some implementations are directed to a computer program product (e.g., a computer-readable storage media such as nonvolatile memory device), having stored thereon instructions which may be executed by a computer (or other electronic device) to perform these operations/activities

Though aspects and features may in some cases be described in individual figures, it will be appreciated that features from one figure can be combined with features of another figure even though the combination is not explicitly shown or explicitly described as a combination.

The methods and system are thought to be applicable to a variety of systems for debugging RTL specifications. Other aspects and features will be apparent to those skilled in the art from consideration of the specification. The methods and system may be implemented as one or more processors configured to execute software, as an application specific integrated circuit (ASIC), or as a logic on a programmable logic device. It is intended that the specification and drawings be considered as examples only, with a true scope of the invention being indicated by the following claims.

What is claimed is:

1. A method comprising:
synthesizing a circuit design specified in a register transfer level (RTL) specification into a netlist by a design tool, wherein the RTL specification includes an assert statement that specifies a conditional expression involving one or more signals specified in the circuit design to be checked during simulation, and the synthesizing includes synthesizing the assert statement into netlist elements;
placing and routing the netlist into a circuit design layout by the design tool; and
generating implementation data from the layout by the design tool.

2. The method of claim 1, wherein the synthesizing includes generating netlist elements that define a status register to capture a logic state of the conditional expression.

3. The method of claim 1, wherein the synthesizing includes generating netlist elements that define a sticky register to capture a logic state of the conditional expression.

4. The method of claim 1, wherein the synthesizing includes, in response to the circuit design including a plurality of assert statements and each assert statement specifying a conditional expression to be evaluated during simulation based on one or more signals specified in the circuit design:
generating for each assert statement of the plurality of assert statements, netlist elements that indicate a result of evaluation of the conditional expression of the assert statement;
generating netlist elements to capture in a status register, the results of evaluation of the conditional expressions of the plurality of assert statements; and
generating a map file that specifies for each assert statement an associated bit position in the status register.

5. The method of claim 4, wherein the circuit design is register transfer level code and generating the map file includes specifying line numbers of the plurality of assert statements in the register transfer level code.

6. The method of claim 1, wherein the synthesizing includes:
generating netlist elements that define a sticky register enabled by a first clock signal having a first frequency to capture a logic state of the conditional expression; and
generating netlist elements that define status register enabled by a second clock signal having a maximum clock frequency of the circuit design to capture the logic state of the conditional expression.

7. The method of claim 1, further comprising:
enabling synthesizing of the assert statement in response to a switch input to the design tool; and
bypassing synthesizing of the assert statement in response to absence of the switch input to the design tool.

8. The method of claim 1, wherein the circuit design includes a plurality of assert statements in a plurality of modules and each assert statement specifies a conditional expression to be evaluated during simulation based on one or more signals specified in the circuit design, and the method further comprising:
enabling synthesizing of each assert statement in a module of the plurality of modules in response to input to the design tool of a switch that identifies the module; and
bypassing synthesizing of each assert statement in a module of the plurality of modules in response to absence of an identifier of the module in the switch.

9. The method of claim 1, wherein the synthesizing includes:
generating netlist elements that enable logic to capture a logic state of the conditional expression in a status register in response to a first state of a control signal; and
generating netlist elements that disable the logic to capture the logic state of the conditional expression in the status register in response to a second state of the control signal.

10. The method of claim 1, wherein the circuit design includes a plurality of assert statements and each assert statement specifies a conditional expression to be evaluated during simulation based on one or more signals specified in the circuit design, and the synthesizing includes:
generating for each assert statement of the plurality of assert statements, netlist elements that enable a result of evaluation of the conditional expression of the assert statement to be captured in a status register, in response to a first state of a control signal associated with the assert statement; and
generating for each assert statement of the plurality of assert statements, netlist elements that disable the capture, in response to a second state of the control signal associated with the assert statement.

11. The method of claim 1, wherein the synthesizing includes:
generating netlist elements that define a status register to capture a logic state of the conditional expression;
generating netlist elements that define a sticky register to capture the logic state of the conditional expression; and
generating netlist elements that clear the status register and the sticky register in response to a control signal.

12. The method of claim 1, further comprising:
operating a programmable integrated circuit configured according to the implementation data by the design tool;
polling a status register indicating a logic state of the conditional expression by the design tool; and
displaying data that identify the assert statement based on the status register.

13. The method of claim 12, further comprising displaying the assert statement from the RTL specification in response to user selection of the data that identify the assert statement.

14. A circuit arrangement, comprising:
a plurality of sticky registers, each sticky register corresponding to an assert statement specified in a circuit design;
detection circuitry configured to:
detect logic states of conditional expressions specified in the assert statements, wherein each conditional expression involves one or more signals of the circuit design; and
store values that indicate the logic states of the conditional expression in the plurality of sticky registers;
a status register;
assertion-enable circuitry coupled to the plurality of sticky registers and configured to sample the sticky registers and to store the values from the sticky registers at bit locations in the status register, each bit location associated with an assert statement; and
readback circuitry coupled to the status register and configured to read and output contents of the status register.

15. The circuit arrangement of claim 14, wherein, a sticky register of the plurality of sticky registers is enabled by a first clock signal having a first frequency, and the status register is enabled by a second clock signal having a maximum clock frequency of the circuit design.

16. The circuit arrangement of claim 14, further comprising:
a control register configured to store bit values, each bit value associated with an assert statement;
wherein the assertion-enable circuitry is configured to:
store a value from a sticky register of the plurality of sticky registers in the status register at a bit location associated with an assert statement in response to a first value of a bit value associated with the assert statement in the control register; and
disable storing the value from the sticky register of the plurality of sticky registers in the status register at the bit location associated with the assert statement in response to a second value of the bit value associated with the assert statement in the control register.

17. The circuit arrangement of claim 14, further comprising clear-hits circuitry coupled to the status register and to the plurality of sticky registers and configured to clear the status register and the sticky registers in response to a control signal.

18. A system comprising:
one or more computer processors configured to execute program code; and
a memory arrangement coupled to the one or more computer processors, wherein the memory arrangement is configured with instructions of a design tool that when executed by the one or more computer processors cause the one or more computer processors to perform operations including:
synthesizing a circuit design specified in a register transfer level (RTL) specification into a netlist, wherein the RTL specification includes an assert statement that specifies a conditional expression involving one or more signals specified in the circuit design to be checked during simulation, and the synthesizing includes synthesizing the assert statement into netlist elements that define a status register and logic to capture in the status register a logic state of the conditional expression;
placing and routing the netlist into a circuit design layout; and
generating implementation data from the layout.

19. The system of claim 18, wherein the instructions for synthesizing include instructions for generating netlist elements that define a sticky register to capture the logic state of the conditional expression.

20. The system of claim 18, wherein:
the logic to capture the logic state of the conditional expression in the status register is enabled in response to a first state of a control signal; and
the logic to capture the logic state of the conditional expression in the status register is disabled in response to a second state of the control signal.
